(19) United States
(12) Patent Application Publication
(10) Pub. No.: US 2026/0060081 A1
(43) Pub. Date: Feb. 26, 2026

(54) SEMICONDUCTOR PACKAGE AND MANUFACTURING METHOD THEREOF

(71) Applicant: Samsung Electronics Co., Ltd., Suwon-si (KR)

(72) Inventors: Jihyun LEE, Suwon-si (KR); Youngbae KIM, Suwon-si (KR); Dongwoon PARK, Suwon-si (KR); Sehoon JANG, Suwon-si (KR)

(73) Assignee: Samsung Electronics Co., Ltd., Suwon-si (KR)

(21) Appl. No.: 19/065,475

(22) Filed: Feb. 27, 2025

(30) Foreign Application Priority Data
Aug. 26, 2024 (KR) 10-2024-0114492

(51) Int. Cl. H01L 23/373; H01L 23/31; H01L 23/538; H01L 25/16

(52) U.S. Cl. CPC H01L 23/3735; H01L 23/5385; H01L 25/162; H01L 23/3107

(57) ABSTRACT

A semiconductor package may include a first redistribution substrate, a first semiconductor device on the first redistribution substrate, through posts on the first redistribution substrate so as to be adjacent to the first semiconductor device, a second redistribution substrate on the first semiconductor device and the through posts, a second semiconductor device on the second redistribution substrate, and a heat-dissipating block on the second redistribution substrate so as to be adjacent to the second semiconductor device. The heat-dissipating block may include a recessed portion at a center portion of a lower surface thereof. The heat-dissipating block may be coupled to the second redistribution substrate through an adhesive layer filling the recessed portion.

### CROSS-REFERENCE TO RELATED APPLICATION

This application is based on and claims priority under 35 U.S.C. § 119 to Korean Patent Application No. 10-2024-0114492, filed on Aug. 26, 2024, in the Korean Intellectual Property Office, the disclosure of which is incorporated by reference herein in its entirety.

### BACKGROUND

Inventive concepts relate to a semiconductor package, and more particularly, to a semiconductor package including a redistribution substrate on and beneath a semiconductor chip and/or a manufacturing method thereof.

Along with the rapid development of the electronics industry and demands of users, electronic devices gradually have been miniaturized and lightened. Along with the miniaturization and lightness of electronic devices, semiconductor packages used therein also have been miniaturized and lightened and may require higher reliability together with higher performance and larger capacity. Along with the higher performance and larger capacity of semiconductor packages, power consumption of the semiconductor packages has increased. Accordingly, in addition to size reduction and performance improvement of semiconductor packages, the significance of the heat-dissipating characteristic of the semiconductor packages has increased.

### SUMMARY

Inventive concepts provides a semiconductor package including a heat-dissipating block, capable of improving the heat-dissipating characteristic of the heat-dissipating block and/or enhancing the structural characteristic of the heat-dissipating block, and/or a manufacturing method thereof.

In addition, aspects of inventive concepts are not limited to the aspects mentioned above, and aspects may be clearly understood by those of ordinary skill in the art from the description below.

According to an example embodiment of inventive concepts, a semiconductor package may include a first redistribution substrate including a first region and a second region next to each other in a first direction; a first semiconductor device on the first region of the first redistribution substrate; through posts on the second region of the first redistribution substrate, such that the first semiconductor device may be adjacent to the through posts in the first direction; a second redistribution substrate on the first semiconductor device and the through posts, the second redistribution substrate including a first region and a second region next to each other in the first direction; a second semiconductor device on the second region of the second redistribution substrate; and a heat-dissipating block on the first region of the second redistribution substrate and adjacent to the second semiconductor device; and an adhesive layer. A center portion of a lower surface of the heat-dissipating block may include a recessed portion. The adhesive layer may fill the recessed portion of the heat-dissipating block and may couple the heat-dissipating block to the second redistribution substrate.

According to an example embodiment of inventive concepts, a semiconductor package may include a first redistribution substrate including a first region and a second region by each other in a first direction; a first semiconductor device on the first region of the first redistribution substrate; through posts on the second region of the first redistribution substrate and adjacent to the first semiconductor device; a second redistribution substrate on the first semiconductor device and the through posts, the second redistribution substrate including a first region and a second region by each other in the first direction; a second semiconductor device on the second region of the second redistribution substrate, the second semiconductor device over the through posts; a heat-dissipating block on the first region of the second redistribution substrate; an adhesive layer on the first region of the second redistribution substrate and over the first semiconductor device, the adhesive layer being adjacent to the second semiconductor device, the adhesive layer between the second redistribution substrate and the heat-dissipating block; and bonding balls along an edge portion of a lower surface of the heat-dissipating block.

According to an example embodiment of inventive concepts, a semiconductor package may include a first redistribution substrate including a first region and a second region next to each other in a first direction; a first semiconductor device on the first region of the first redistribution substrate; through posts on the second region of the first redistribution substrate and adjacent to the first semiconductor device; a second redistribution substrate on the first semiconductor device and the through posts, the second redistribution substrate including a first region and a second region next to each other in the first direction; a second semiconductor device on the second region of the second redistribution substrate; an adhesive layer and bonding balls on first region of the second redistribution substrate and adjacent to the second semiconductor device; a heat-dissipating block connected to the first region of the second redistribution substrate through the bonding balls and the adhesive layer; and a sealant between the first redistribution substrate and the second redistribution substrate, the sealant sealing the first semiconductor device and the through posts. A center portion of a lower surface of the heat-dissipating block may include a recessed portion. An edge portion of the lower surface of the heat-dissipating block may include a protruding portion. The protruding portion of the heat-dissipating block may surround the recessed portion of the heat-dissipating block. The adhesive layer may fill the recessed portion of the heat-dissipating block. The protruding portion may have a slit forming an opening in fluid communication with the recessed portion of the heat-dissipating block.

### BRIEF DESCRIPTION OF THE DRAWINGS

Embodiments of inventive concepts will be more clearly understood from the following detailed description taken in conjunction with the accompanying drawings in which:

FIG. 1 is a cross-sectional view of a semiconductor package according to an embodiment;

FIGS. 2A to 2C are a top view of the semiconductor package of FIG. 1 and a bottom view and a lateral view of a heat-dissipating block, respectively;

FIGS. 3A to 3C are cross-sectional views illustrating structures of a second semiconductor device in the semiconductor package of FIG. 1 in more detail;

FIG. 4 is a cross-sectional view of a semiconductor package according to an embodiment;

FIGS. 5A and 5B are a cross-sectional view of a semiconductor package according to an embodiment and a bottom view of a heat-dissipating block, respectively;

FIGS. 6A and 6B are a top view and a cross-sectional view of semiconductor packages according to embodiments, respectively; and

FIGS. 7A to 7I are cross-sectional views schematically illustrating a method of manufacturing a semiconductor package, according to an embodiment.

### DETAILED DESCRIPTION OF THE EMBODIMENTS

Hereinafter, embodiments are described in detail with reference to the accompanying drawings. Like reference numerals in the drawings denote like elements, and thus their repetitive description will be omitted.

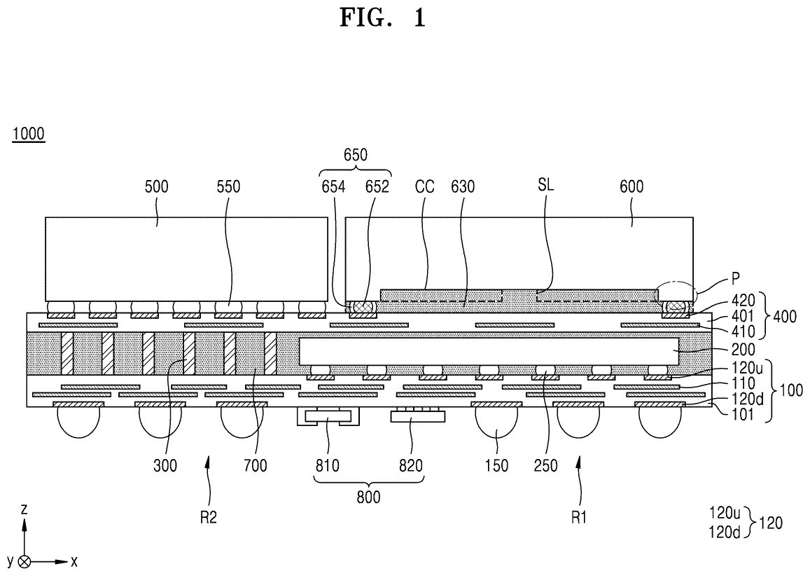

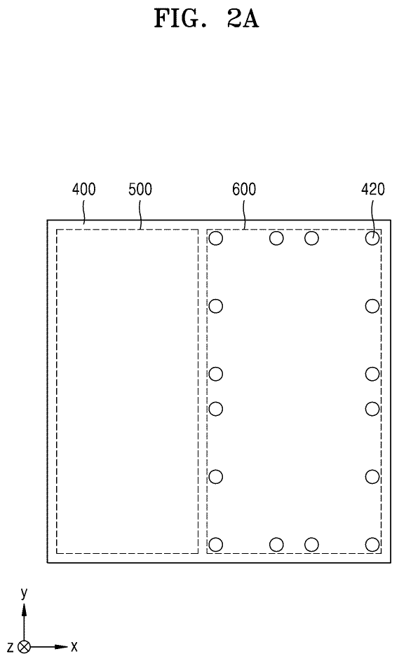

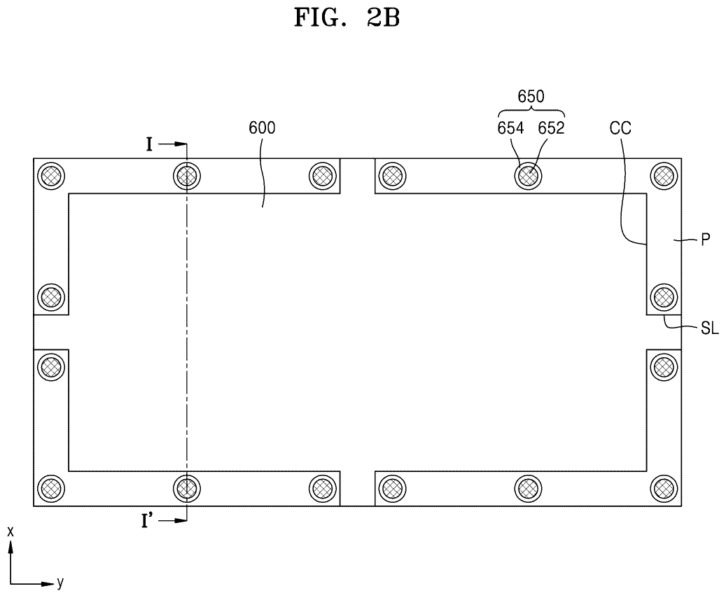

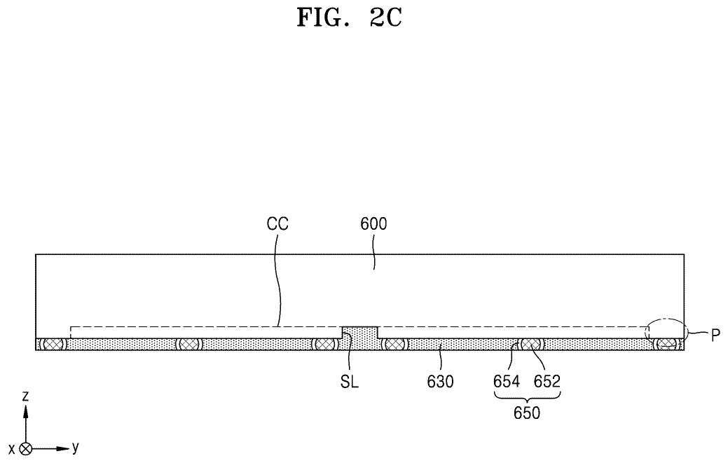

FIG. 1 is a cross-sectional view of a semiconductor package 1000 according to an embodiment, and FIGS. 2A to 2C are a top view of the semiconductor package 1000 of FIG. 1 and a bottom view and a lateral view of a heat-dissipating block 600, respectively.

Referring to FIGS. 1 to 2C, the semiconductor package 1000 of the present embodiment may include a first redistribution substrate 100, a first semiconductor device 200, through posts 300, a second redistribution substrate 400, a second semiconductor device 500, the heat-dissipating block 600, a sealant 700, and a passive device 800.

The first redistribution substrate 100 may be beneath the first semiconductor device 200, the through posts 300, and the sealant 700. The first redistribution substrate 100 may redistribute a chip pad of the first semiconductor device 200 to an external region of the first semiconductor device 200. The first redistribution substrate 100 may include a first body insulating layer 101, a first redistribution line 110, and a substrate pad 120.

The first body insulating layer 101 may include an insulating material, e.g., a photo imageable dielectric (PID) or a photo imageable polyimide (PIP) resin, and further include an inorganic filler. However, the material of the first body insulating layer 101 is not limited to the materials described above. For example, the first body insulating layer 101 may include polyimide isoindolo quinazolinedione (PIQ), polyimide (PI), polybenzoxazole (PBO), or the like.

The first body insulating layer 101 may have a multi-layer structure as well as the multi-layer structure of the first redistribution line 110. However, FIG. 1 shows for convenience that the first body insulating layer 101 has a single-layer structure. When the first body insulating layer 101 has a multi-layer structure, all the layers of the first body insulating layer 101 may include the same material, or at least one of the layers of the first body insulating layer 101 may include a different material.

The first redistribution line 110 may have a multi-layer structure in the first body insulating layer 101. First redistribution lines 110 in different layers may be connected to each other by a vertical via. As a reference, the vertical via is not shown in FIG. 1. The first redistribution line 110 and the vertical via may include, for example, copper (Cu). However, the material of the first redistribution line 110 and the vertical via is not limited to Cu.

The substrate pad 120 may include an upper substrate pad 120u on the upper surface of the first redistribution substrate 100 and a lower substrate pad 120d on the lower surface of the first redistribution substrate 100. A first connection terminal 250 may be on the upper substrate pad 120u. An external connection terminal 150 may be on the lower substrate pad 120d. In some embodiments, the substrate pad 120 may be included as a portion of the first redistribution line 110.

The first semiconductor device 200 may be mounted on the first redistribution substrate 100 through the first connection terminal 250. The first connection terminal 250 may include a metal pillar or solder. In some embodiments, the first connection terminal 250 may include both the metal pillar and the solder. Herein, the metal pillar may include, for example, Cu. However, the material of the metal pillar is not limited to Cu.

The first semiconductor device 200 may be on the first redistribution substrate 100 and at any one side in an x direction. For example, as shown in FIG. 1, the first semiconductor device 200 may be on the first redistribution substrate 100 and to the right in the x direction. In addition, in response that the first semiconductor device 200 is to the right in the x direction, the heat-dissipating block 600 on the second redistribution substrate 400 may also be to the right so as to correspond to the first semiconductor device 200. This arrangement structure may be to effectively discharge, through the heat-dissipating block 600, heat generated by the first semiconductor device 200. The first redistribution substrate 100 and the second redistribution substrate 400 each may include a first region R1 and a second region R2 next to each other in the x direction. The first semiconductor device 200 may be on the first region R1 of the first redistribution substrate 100 and the through posts 300 may be on a second region R2 of the first redistribution substrate 100. The heat-dissipating block 600 may be on the first region R1 of the second redistribution substrate 400, which may be over the first semiconductor device 200 on the first region R1 of the first redistribution substrate 100. The second semiconductor device 500 may be on the second region R2 of the second redistribution substrate 400, which may be over the through posts 300 on the second region R2 of the first redistribution substrate 100.

The first semiconductor device 200 may include one logic chip. Accordingly, the first semiconductor device 200 may include a plurality of logic devices therein. Herein, the plurality of logic devices are devices configured to perform various kinds of signal processing and include, for example, an AND, an OR, a NOT, a flip-flop, and the like. In the semiconductor package 1000 of the present embodiment, the first semiconductor device 200 may include, for example, an application processor (AP) chip. Alternatively, the first semiconductor device 200 may include a control chip, a processor chip, a central processing unit (CPU) chip, a graphics processing unit (GPU) chip, a neutral processing unit (NPU) chip, or the like. Alternatively, the first semiconductor device 200 may include a system on chip (SoC).

The first semiconductor device 200 may include a substrate and an active layer. The substrate may include silicon (Si), e.g., monocrystalline Si, polycrystalline Si (poly-Si), or amorphous Si. However, the material of the substrate is not limited to Si. For example, in some embodiments, the substrate may include a group IV semiconductor, such as germanium (Ge), a group IV-IV compound semiconductor, such as silicon germanium (SiGe) or silicon carbide (SIC), or a group III-V compound semiconductor, such as gallium arsenide (GaAs), indium arsenide (InAs), or indium phosphide (InP).

The active layer may be beneath the substrate. The active layer may include an integrated circuit layer and a multi-wiring layer. The integrated circuit layer may be formed using an impurity region at a lower portion of the substrate. For example, the integrated circuit layer may include transistors each including an impurity region, such as a source/drain region, and a gate electrode. However, elements included in the integrated circuit layer are not limited to a transistor. The multi-wiring layer may be beneath the integrated circuit layer. The multi-wiring layer may include multi-layer wiring lines, and wiring lines in different layers may be connected to each other through a via. A chip pad connected to the wiring lines of the multi-wiring layer may be on the lower surface of the active layer. In some embodiments, the chip pad may be included as a portion of the wiring lines of the multi-wiring layer.

In the first semiconductor device 200, the lower surface may be a front-side that is an active surface, and the upper surface may be a back-side that is an inactive surface. In other words, the lower surface of the active layer may correspond to the front-side of the first semiconductor device 200, and the upper surface of the substrate may correspond to the back-side of the first semiconductor device 200. The chip pad may be formed on the front-side that is the active surface, and the first connection terminal 250 may be on the chip pad. That is, the first connection terminal 250 may connect the chip pad of the first semiconductor device 200 to the upper substrate pad 120u of the first redistribution substrate 100.

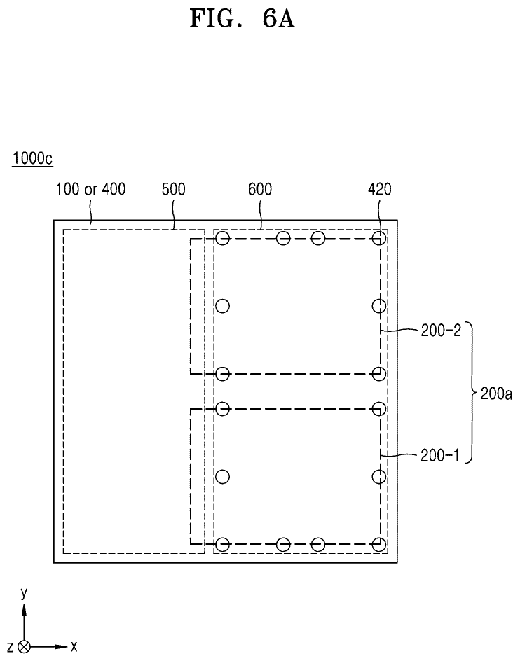

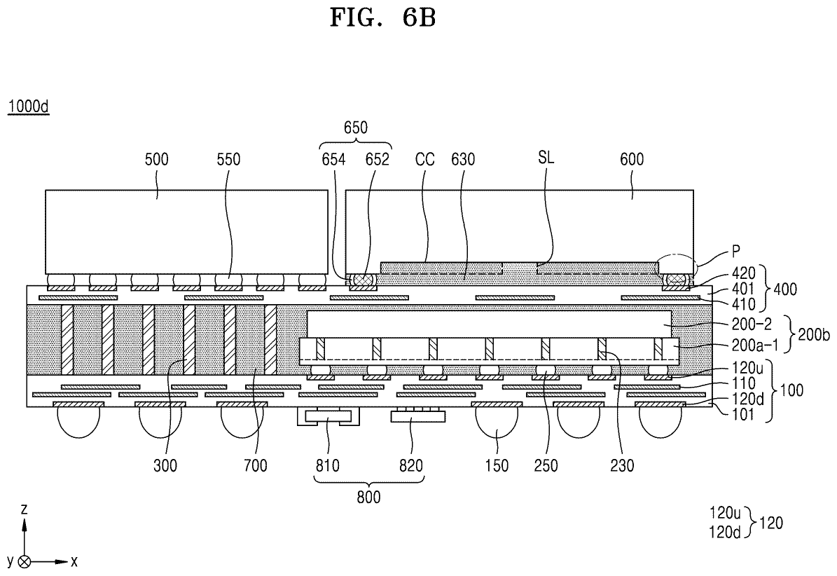

In some embodiments, the first semiconductor device 200 may include two or more logic chips. Embodiments in which the first semiconductor device 200 includes two logic chips are described in more detail with reference to FIGS. 6A and 6B.

The through posts 300 may be on the first redistribution substrate 100 and to the left of the first semiconductor device 200 in the x direction. In addition, the through posts 300 may be between the first redistribution substrate 100 and the second redistribution substrate 400 at a portion where the first semiconductor device 200 is not arranged. Because the sealant 700 is between the first redistribution substrate 100 and the second redistribution substrate 400, the through posts 300 may have a structure extending in a z direction through the sealant 700. The through posts 300 may connect the first redistribution substrate 100 to the second redistribution substrate 400. For example, the lower surface of a through post 300 may be connected to the first redistribution line 110 of the first redistribution substrate 100, and the upper surface of the through post 300 may be connected to a second redistribution line 410 of the second redistribution substrate 400.

The left and the right in the x direction may be relative concepts. Therefore, the positions of the first semiconductor device 200 and the through posts 300 may be exchanged. For example, the first semiconductor device 200 may be to the left in the x direction, and the through posts 300 may be at the right of the first semiconductor device 200 in the x direction. In addition, the heat-dissipating block 600 may be to the left in the x direction so as to correspond to the first semiconductor device 200, and the second semiconductor device 500 may be to the right in the x direction.

The through post 300 may include, for example, Cu. Accordingly, the through post 300 may be referred to as a Cu-post. However, the material of the through post 300 is not limited to Cu. The through posts 300 may be formed through electroplating using a seed metal layer. The seed metal layer may include various metal materials, e.g., Cu, titanium (Ti), tantalum (Ta), titanium nitride (TIN), and tantalum nitride (TaN). In the semiconductor package 1000 of the present embodiment, the seed metal layer may be included as a portion of the through post 300. Accordingly, the seed metal layer is not separately shown in FIG. 1.

The second redistribution substrate 400 may be on the first semiconductor device 200, the through posts 300, and the sealant 700. The second redistribution substrate 400 may have a similar structure to that of the first redistribution substrate 100 but have a different thickness from that of the first redistribution substrate 100. For example, the second redistribution substrate 400 may include a second body insulating layer 401, the second redistribution line 410, and a substrate pad 420. The number of layers of the second redistribution line 410 of the second redistribution substrate 400 may be less than the number of layers of the first redistribution line 110 of the first redistribution substrate 100. However, in some embodiments, the number of layers of the second redistribution line 410 of the second redistribution substrate 400 may be substantially the same as the number of layers of the first redistribution line 110 of the first redistribution substrate 100. The notion that elements are “substantially the same” may indicate that the element may be completely the same and may also indicate that the elements may be determined to be the same in consideration of errors or deviations occurring during a process. The second redistribution line 410 of the second redistribution substrate 400 may be connected to the external connection terminal 150 and the first semiconductor device 200 through the through posts 300 and the first redistribution line 110 of the first redistribution substrate 100.

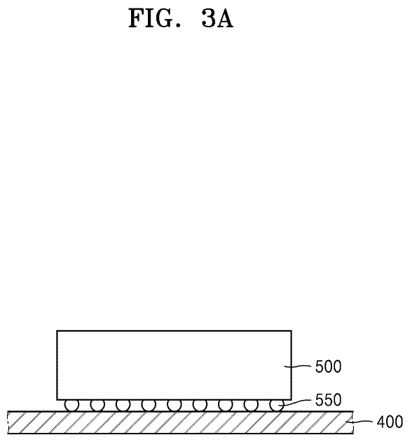

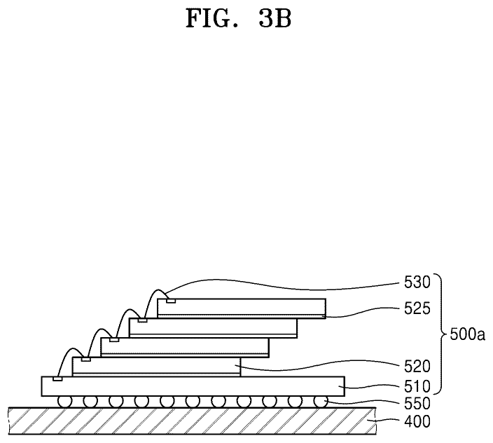

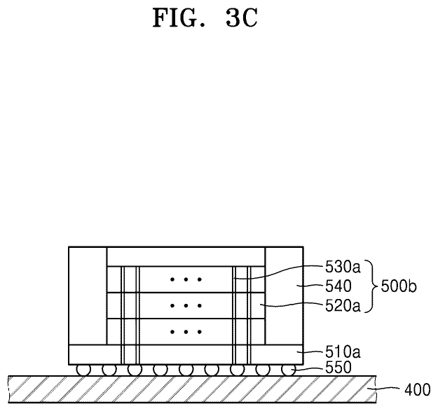

The second semiconductor device 500 may be mounted on the second redistribution substrate 400 through a second connection terminal 550. The second semiconductor device 500 may be on the second redistribution substrate 400 and to the left in the x direction so as to correspond to the through posts 300. The second semiconductor device 500 may have a single-chip structure or a package structure. For example, when the second semiconductor device 500 has a single-chip structure, the second semiconductor device 500 may include one memory chip. When the second semiconductor device 500 has a package structure, the second semiconductor device 500 may include, for example, a plurality of memory chips. The memory chip of the second semiconductor device 500 may include, for example, a volatile memory device, such as dynamic random access memory (DRAM) or static random access memory (SRAM), or a non-volatile memory device, such as flash memory. In the semiconductor package 1000 of the present embodiment, the second semiconductor device 500 may include, for example, a DRAM chip. However, the type of the second semiconductor device 500 is not limited to the DRAM chip. The single-chip structure or package structure of the second semiconductor device 500 is described in more detail with reference to FIGS. 3A to 3C.

When the second semiconductor device 500 is a package, the semiconductor package 1000 of the present embodiment may correspond to a package on package (POP) structure. For example, in the semiconductor package 1000 of the present embodiment, the first redistribution substrate 100, the first semiconductor device 200, the through post 300, and the second redistribution substrate 400 may constitute a lower package, and the second semiconductor device 500 having a package structure may constitute an upper package. Accordingly, the semiconductor package 1000 of the present embodiment may have a POP structure in which the upper package is stacked on the lower package.

The heat-dissipating block 600 may be stacked on the second redistribution substrate 400 and to the left in the x direction so as to be adjacent to the second semiconductor device 500. The heat-dissipating block 600 may be stacked on the second redistribution substrate 400 through an adhesive layer 630 and bonding balls 650. The heat-dissipating block 600 may include, for example, a heat sink or a heat slug. In some embodiments, the heat-dissipating block 600 may be referred to as a heat path block (HPB).

The heat-dissipating block 600 may generally have a rectangular parallelepiped structure. As shown in FIGS. 2B and 2C, a recessed portion CC may be formed at a center portion of the lower surface of the heat-dissipating block 600. As a reference, in the semiconductor package 1000 of FIG. 1, the heat-dissipating block 600 may correspond to a cross-sectional view taken along line I-I′ of FIG. 2B.

The recessed portion CC may be surrounded by a protruding portion P extending along an edge portion on the lower surface of the heat-dissipating block 600. Particularly, the protruding portion P may have a structure protruding downward from the upper surface of the recessed portion CC. In addition, the protruding portion P may extend in the x direction or a y direction along the edge portion on the lower surface of the heat-dissipating block 600. A slit SL may be formed in the protruding portion P. The slit SL may open the recessed portion CC in a lateral direction. For example, the upper surface of the recessed portion CC may have substantially the same vertical level as the upper surface of the slit SL.

As shown in FIG. 2B, the protruding portion P may extend in the x direction or the y direction so as to correspond to the four sides of a rectangle, and one slit SL may be formed in the protruding portion P of each side. However, the number of slits SL of the protruding portion P is not limited thereto. For example, a plurality of slits SL may be formed in the protruding portion P of each side.

As shown in FIG. 1, the recessed portion CC and the slit SL may be filled with the adhesive layer 630. In addition, the thickness of the adhesive layer 630 in the z direction may be greater than the depth of the recessed portion CC. Particularly, the z-direction thickness of the adhesive layer 630 in the recessed portion CC may be the same as the sum of the depth of the recessed portion CC (or the height of the protruding portion P) and the height of a bonding ball 650 (or the gap between the protruding portion P and the second redistribution substrate 400). Accordingly, the adhesive layer 630 may protrude downward from the recessed portion CC in the z direction and fill between the bonding balls 650 on the lower surface of the protruding portion P.

The adhesive layer 630 may fix the heat-dissipating block 600 onto the second redistribution substrate 400 in an adhesive manner. In some embodiments, the adhesive layer 630 may have a structure slightly protruding outward from the side surfaces of the heat-dissipating block 600 on the lower surface of the heat-dissipating block 600. The adhesive layer 630 may include a material having a high heat conductivity to efficiently transfer heat from the first semiconductor device 200 to the heat-dissipating block 600. For example, the adhesive layer 630 may include a thermal interface material (TIM), a heat-conductive resin, a heat-conductive polymer, silicon oxide, such as SiO₂, silicon nitride, such as SiCN, or the like. Herein, the TIM may include a material having a high heat conductivity, that is, a material having a low thermal resistance, such as Si, grease, tape, an elastomer-filled pad, or a phase transition material. In the semiconductor package 1000 of the present embodiment, the adhesive layer 630 may include Si as the TIM.

The bonding balls 650 may be on the lower surface of the protruding portion P, as shown in FIG. 2B. In addition, the bonding balls 650 may be on the substrate pad 420 of the second redistribution substrate 400. In more detail with reference to FIGS. 2A and 2B, FIG. 2A shows the upper surface of the second redistribution substrate 400, wherein dotted rectangles may indicate regions occupied by the second semiconductor device 500 and the heat-dissipating block 600, respectively. In addition, small circles in the region of the heat-dissipating block 600 may correspond to substrate pads 420 on which the bonding balls 650 are disposed. Therefore, the substrate pads 420 may one-to-one correspond to the bonding balls 650 on the lower surface of the heat-dissipating block 600.

As a reference, the bottom view of the heat-dissipating block 600 of FIG. 2B shows a state in which only the bonding balls 650 are on the lower surface of the heat-dissipating block 600 where the adhesive layer 630 is not disposed. However, the lateral view of the heat-dissipating block 600 of FIG. 2C shows a state in which the adhesive layer 630 and the bonding balls 650 are on the lower surface of the heat-dissipating block 600.

The bonding ball 650 may include a Cu ball 652 at the center thereof and a solder ball 654 outside the Cu ball 652. In some embodiments, according to the material and structure of the bonding ball 650, the bonding ball 650 may be referred to as a Cu core solder ball (CCSB). Because Cu has a very high heat conductivity, the bonding ball 650 may significantly increase a heat conductivity. Accordingly, the bonding balls 650 may efficiently transfer heat from the first semiconductor device 200 to the heat-dissipating block 600 together with the adhesive layer 630. However, the material and structure of the bonding ball 650 are not limited to the material and structure described above. For example, the bonding ball 650 may include a metal material having a high heat conductivity and may have various single-layer or multi-layer structures.

The sealant 700 may be between the first redistribution substrate 100 and the second redistribution substrate 400. The sealant 700 may cover and seal the side surfaces of the through posts 300 and the side surfaces and the upper surface of the first semiconductor device 200. In some embodiments, the upper surface of the first semiconductor device 200 may be in contact with the lower surface of the second redistribution substrate 400. In this case, the sealant 700 may not be between the first semiconductor device 200 and the second redistribution substrate 400.

The sealant 700 may include an insulating material, e.g., a thermosetting resin, such as an epoxy resin, a thermoplastic resin, such as PI, or a resin containing a reinforcement material, such as an inorganic filler, in addition to the same. For example, the sealant 700 may include an Ajinomoto build-up film (ABF), fire retardant class 4 (FR-4), a bismaleimide triazine (BT) resin, or the like. In addition, the sealant 700 may include a molding material, such as an epoxy molding compound (EMC), or a photosensitive material, such as a photo imageable encapsulant (PIE). However, the material of the sealant 700 is not limited to the materials described above.

In some embodiments, an upper sealant covering the side surfaces of the second semiconductor device 500 and the heat-dissipating block 600 may be on the second redistribution substrate 400. The upper sealant may fill between the second redistribution substrate 400 and the second semiconductor device 500 and between second connection terminals 550. In addition, the upper sealant may cover the side surfaces of the adhesive layer 630 beneath the heat-dissipating block 600. In some embodiments, an underfill may fill between the second semiconductor device 500 and the second redistribution substrate 400 and between the second connection terminals 550, and the upper sealant may cover the side surfaces of the underfill.

The external connection terminal 150 may be on the lower substrate pad 120d on the lower surface of the first redistribution substrate 100. The external connection terminal 150 may be electrically connected to the first redistribution line 110 via the lower substrate pad 120d. Therefore, the external connection terminal 150 may be connected to the first semiconductor device 200 via the first redistribution substrate 100 and the first connection terminal 250. In addition, the external connection terminal 150 may be connected to the second semiconductor device 500 via the first redistribution substrate 100, the through post 300, and the second connection terminal 550.

The external connection terminal 150 may connect the semiconductor package 1000 to a package substrate of an external system, a mainboard of an electronic device, such as a mobile device, or the like. The external connection terminal 150 may include a conductive material, e.g., at least one of solder, tin (Sn), silver (Ag), Cu, and aluminum (Al). However, the material of the external connection terminal 150 is not limited to the materials described above.

As a reference, as shown in FIG. 1, the external connection terminal 150 may be arranged in a region wider than the lower surface of the first semiconductor device 200. As such, a structure in which the external connection terminal 150 is arranged in a region wider than the lower surface of the first semiconductor device 200 is referred to as a fan-out (FO) package structure. However, a structure in which the external connection terminal 150 is arranged only in a region corresponding to the lower surface of the first semiconductor device 200 is referred to as a fan-in (FI) package structure.

The passive device 800 may be on the lower surface of the first redistribution substrate 100. According to an embodiment, the passive device 800 may be on the upper surface of or inside the first redistribution substrate 100. In addition, the passive device 800 may be on the lower or upper surface of or inside the second redistribution substrate 400. The passive device 800 may include a two-terminal device, such as a resistor, an inductor, or a capacitor. In the semiconductor package 1000 of the present embodiment, the passive device 800 may include a multi-layer ceramic capacitor (MLCC) 810 and a Si-capacitor 820.

In the semiconductor package 1000 of the present embodiment, the heat-dissipating block 600 may include the recessed portion CC in the lower surface thereof and may be stacked on the second redistribution substrate 400 through the adhesive layer 630 and the bonding balls 650. Accordingly, the semiconductor package 1000 of the present embodiment may have an improved heat-dissipating characteristic of the heat-dissipating block 600 and provide several strengths according to the structure of the heat-dissipating block 600. The several strengths are more particularly described as follows.

First, the recessed portion CC may be formed in the lower surface of the heat-dissipating block 600, thereby more easily satisfying a bond line thickness (BLT) specification. Herein the BLT may indicate a standard for the thickness of the adhesive layer 630. In the semiconductor package 1000 of the present embodiment, because the thickness of the adhesive layer 630 may be covered as much as the depth of the recessed portion CC, by including the recessed portion CC in the lower surface of the heat-dissipating block 600, it may be easier to meet the BLT specification.

Second, because the adhesive layer 630 is coupled to the second redistribution substrate 400 in a form of filling the recessed portion CC and then spreading outward, the filling coverage of the adhesive layer 630 between the heat-dissipating block 600 and the second redistribution substrate 400 may increase. This increase in the filling coverage may contribute to the limiting and/or minimizing an air layer between the heat-dissipating block 600 and the second redistribution substrate 400. This increase in the filling coverage may improve heat transfer efficiency due to the adhesive layer 630 and accordingly may improve a heat discharge characteristic through the heat-dissipating block 600.

Third, because the heat-dissipating block 600 is stacked on the second redistribution substrate 400 by using the bonding balls 650, misalignment of the heat-dissipating block 600 may be limited and/or reduced. In other words, by more accurately aligning and coupling the bonding balls 650 with the substrate pads 420 of the second redistribution substrate 400, the heat-dissipating block 600 may be more accurately aligned and may be stacked in a determined region of the second redistribution substrate 400.

Fourth, because the heat-dissipating block 600 is stacked on the second redistribution substrate 400 by using the bonding balls 650, the tilt of the heat-dissipating block 600 on the second redistribution substrate 400 may be reduced. The adhesive layer 630 may be difficult to control because of viscosity. Accordingly, when the heat-dissipating block 600 is stacked only using the adhesive layer 630, the thickness of the adhesive layer 630 may vary according to positions, thereby tilting the heat-dissipating block 600. However, in the semiconductor package 1000 of the present embodiment, the bonding balls 650 on the edge portion of the lower surface of the heat-dissipating block 600 may be directly coupled to the substrate pads 420 of the second redistribution substrate 400, thereby solving the tilt of the heat-dissipating block 600.

Fifth, by precisely adjusting the height of the heat-dissipating block 600 through the bonding balls 650, the level difference between the heat-dissipating block 600 and the second semiconductor device 500 adjacent thereto may be reduced. As described above, because of the viscosity of the adhesive layer 630, when the heat-dissipating block 600 is stacked using only the adhesive layer 630, the thickness of the adhesive layer 630 may be difficult to adjust, and accordingly, the height of the heat-dissipating block 600 may be difficult to adjust. Therefore, the level difference between the heat-dissipating block 600 and the second semiconductor device 500 adjacent thereto may occur. However, in the semiconductor package 1000 of the present embodiment, by stacking the heat-dissipating block 600 on the second redistribution substrate 400 through the bonding balls 650, the height of the heat-dissipating block 600 may be precisely adjusted, and accordingly, the level difference between the heat-dissipating block 600 and the second semiconductor device 500 adjacent thereto may be reduced.

FIGS. 3A to 3C are cross-sectional views illustrating structures of a second semiconductor device in the semiconductor package 1000 of FIG. 1 in more detail. FIG. 1 is also referred to for description, and the description made with reference to FIGS. 1 to 2C is simply repeated or omitted.

Referring to FIG. 3A, the second semiconductor device 500 may include one memory chip. The memory chip may include a volatile memory device, such as DRAM or SRAM, or a non-volatile memory device, such as flash memory. In the semiconductor package 1000 of the present embodiment, the second semiconductor device 500 may include, for example, a DRAM chip. The second semiconductor device 500 may be mounted on the second redistribution substrate 400 through a flip-chip bonding structure using the second connection terminal 550. The second connection terminal 550 may include both a pillar and solder or include only the solder.

Referring to FIG. 3B, a second semiconductor device 500a may include a semiconductor package having a wire bonding structure. Particularly, the second semiconductor device 500a may include a package substrate 510 and a plurality of memory chips 520 stacked on the package substrate 510. The plurality of memory chips 520 may be mounted on the package substrate 510 through a wire bonding structure using an adhesive layer 525 and a wire 530. A memory chip 520 of the second semiconductor device 500a may include a volatile memory device, such as DRAM or SRAM, or a non-volatile memory device, such as flash memory. In the semiconductor package 1000 of the present embodiment, the memory chip 520 of the second semiconductor device 500a may include, for example, a DRAM chip. In addition, the second semiconductor device 500a may include, on the package substrate 510, an internal sealant that seals the plurality of memory chips 520 and the wire 530. However, for convenience, the internal sealant is omitted in FIG. 3B.

Although FIG. 3B shows that four memory chips 520 are stacked on the package substrate 510, the number of memory chips 520 is not limited to 4. For example, three or less or five or more memory chips 520 may be stacked on the package substrate 510. In addition, the memory chip 520 is not limited to a stepped structure and may be stacked on the package substrate 510 in a zigzag structure or a combination of the stepped structure and the zigzag structure. The second semiconductor device 500a having a package structure may also be mounted on the second redistribution substrate 400 through the second connection terminal 550.

Referring to FIG. 3C, a second semiconductor device 500b may include a high bandwidth memory (HBM) package. Particularly, the second semiconductor device 500b may include a base chip 510a, a plurality of core chips 520a stacked on the base chip 510a, and an internal sealant 540. In addition, each of the base chip 510a and the plurality of core chips 520a may include a through electrode 530a therein. However, the uppermost core chip 520a among the plurality of core chips 520a may not include the through electrode 530a.

The base chip 510a may include logic devices. Accordingly, the base chip 510a may be a logic chip. The base chip 510a may be beneath the plurality of core chips 520a, integrate signals of the plurality of core chips 520a and transmit the integrated signal to the outside, and transmit a signal and power from the outside to the plurality of core chips 520a. Accordingly, the base chip 510a may be referred to as a buffer chip or a control chip. Each of the plurality of core chips 520a may be a memory chip. For example, each of the plurality of core chips 520a may be a DRAM chip. Each of the plurality of core chips 520a may be stacked on the base chip 510a or a core chip 520a therebeneath through pad-to-pad bonding, hybrid bonding (HB), bonding using a connection terminal, bonding using an anisotropic conductive film (ACF), or the like. Although FIG. 3C shows that four core chips 520a are stacked on the base chip 510a, the number of core chips 520a is not limited to 4. For example, three or less or five or more core chips 520a may be stacked on the base chip 510a.

The second connection terminal 550 may be on the lower surface of the base chip 510a. Therefore, the second semiconductor device 500b of an HBM package may also be mounted on the second redistribution substrate 400 through the second connection terminal 550. The plurality of core chips 520a on the base chip 510a may be sealed by the internal sealant 540. However, the upper surface of the uppermost core chip 520a among the plurality of core chips 520a may not be covered by the internal sealant 540. However, in some embodiments, the upper surface of the uppermost core chip 520a may be covered by the internal sealant 540.

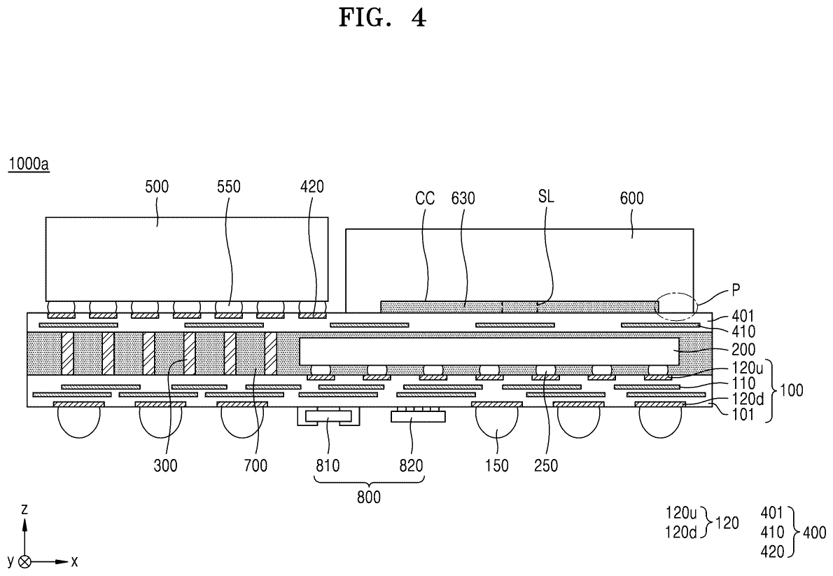

FIG. 4 is a cross-sectional view of a semiconductor package 1000a according to an embodiment. The description made with reference to FIGS. 1 to 3C is simply repeated or omitted.

Referring to FIG. 4, the semiconductor package 1000a of the present embodiment may differ from the semiconductor package 1000 of FIG. 1 in that the heat-dissipating block 600 is stacked on the second redistribution substrate 400 through only the adhesive layer 630. Particularly, the semiconductor package 1000a of the present embodiment may include the first redistribution substrate 100, the first semiconductor device 200, the through post 300, the second redistribution substrate 400, the second semiconductor device 500, the heat-dissipating block 600, the sealant 700, and the passive device 800. The first redistribution substrate 100, the first semiconductor device 200, the through post 300, the second redistribution substrate 400, the second semiconductor device 500, the sealant 700, and the passive device 800 are the same as described for the semiconductor package 1000 of FIG. 1.

The heat-dissipating block 600 may have substantially the same structure as the heat-dissipating block 600 of the semiconductor package 1000 of FIG. 1. For example, the recessed portion CC may be formed at a center portion of the lower surface of the heat-dissipating block 600. The recessed portion CC may be surrounded by the protruding portion P extending along an edge portion on the lower surface of the heat-dissipating block 600. In addition, the protruding portion P may have the slit SL formed to open the recessed portion CC therethrough in a lateral direction.

In the semiconductor package 1000a of the present embodiment, the heat-dissipating block 600 may be stacked on the second redistribution substrate 400 by using only the adhesive layer 630 without bonding balls. The adhesive layer 630 may fill the recessed portion CC and the slit SL of the protruding portion P. As shown in FIG. 4, the adhesive layer 630 may not be between the protruding portion P and the second redistribution substrate 400, and accordingly, the lower surface of the protruding portion P may be in direct contact with the upper surface of the second redistribution substrate 400. For example, the thickness of the adhesive layer 630 in the z direction may be substantially the same as the depth of the recessed portion CC or the height of the protruding portion P.

In some embodiments, the adhesive layer 630 may be between the protruding portion P and the second redistribution substrate 400. In the some embodiments, the thickness of the adhesive layer 630 in the z direction at the recessed portion CC may be the sum of the depth of the recessed portion CC and the gap between the protruding portion P and the second redistribution substrate 400. In addition, in some embodiments, the adhesive layer 630 may have a structure slightly protruding outward from the side surfaces of the heat-dissipating block 600 at the slit SL of the protruding portion P.

Because the heat-dissipating block 600 is stacked on the second redistribution substrate 400 by using only the adhesive layer 630, no substrate pad may be on a portion of the second redistribution substrate 400 corresponding to the heat-dissipating block 600. That is, only the substrate pad 420 coupled to the second connection terminal 550 of the second semiconductor device 500 may be on the second redistribution substrate 400.

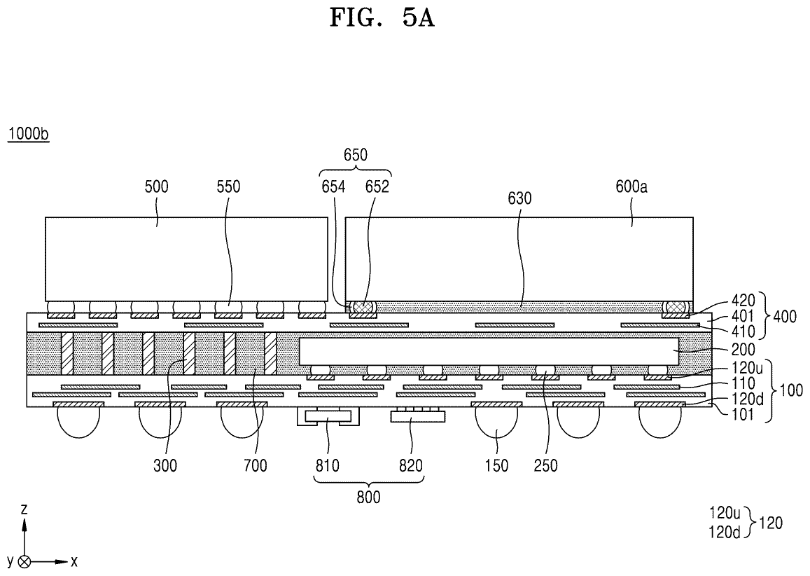

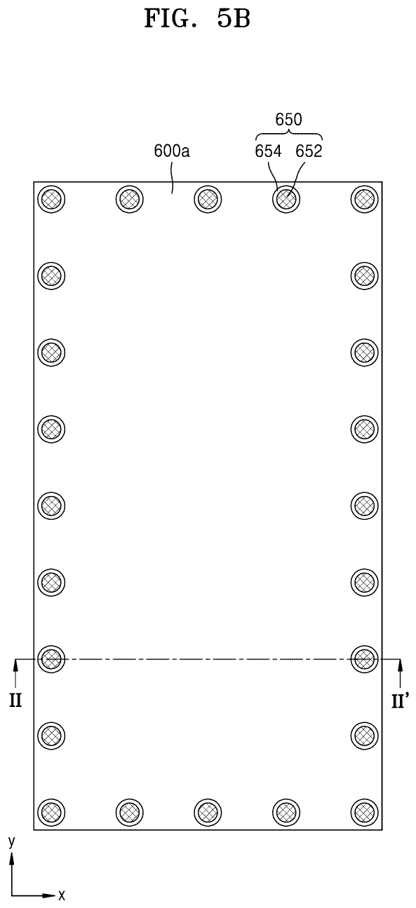

FIGS. 5A and 5B are a cross-sectional view of a semiconductor package 1000b according to an embodiment and a bottom view of a heat-dissipating block 600a, respectively. The description made with reference to FIGS. 1 to 4 is simply repeated or omitted.

Referring to FIGS. 5A and 5B, the semiconductor package 1000b of the present embodiment may differ from the semiconductor package 1000 of FIG. 1 in the structure of the heat-dissipating block 600a. Particularly, the semiconductor package 1000b of the present embodiment may include the first redistribution substrate 100, the first semiconductor device 200, the through post 300, the second redistribution substrate 400, the second semiconductor device 500, the heat-dissipating block 600a, the sealant 700, and the passive device 800. The first redistribution substrate 100, the first semiconductor device 200, the through post 300, the second redistribution substrate 400, the second semiconductor device 500, the sealant 700, and the passive device 800 are the same as described for the semiconductor package 1000 of FIG. 1.

In the semiconductor package 1000b of the present embodiment, the heat-dissipating block 600a may be stacked on the second redistribution substrate 400 through the adhesive layer 630 and the bonding balls 650. However, unlike the heat-dissipating block 600 of the semiconductor package 1000 of FIG. 1, the heat-dissipating block 600a may not have a recessed portion in the lower surface thereof. Accordingly, the lower surface of the heat-dissipating block 600a may generally have the same height level.

As shown in FIG. 5B, the bonding balls 650 may be arranged along an edge portion of the lower surface of the heat-dissipating block 600a. Although FIG. 5B shows that the bonding balls 650 are arranged in one column or one row, in some embodiments, the bonding balls 650 may be arranged along the edge portion of the lower surface of the heat-dissipating block 600a in a plurality of columns or a plurality of rows.

As a reference, in the semiconductor package 1000b of FIG. 5A, the heat-dissipating block 600a may correspond to a cross-sectional view taken along line II-II′ of FIG. 5B. In addition, the bottom view of the heat-dissipating block 600a of FIG. 5B shows a state in which only the bonding balls 650 are on the lower surface of the heat-dissipating block 600a but the adhesive layer 630 is not arranged. In addition, when the heat-dissipating block 600a is stacked on the second redistribution substrate 400 through the adhesive layer 630 and the bonding balls 650, the adhesive layer 630 may fill between the bonding balls 650 by extending from a center portion of the heat-dissipating block 600a.

In the semiconductor package 1000b of the present embodiment, because the heat-dissipating block 600a is stacked on the second redistribution substrate 400 by using the adhesive layer 630 and the bonding balls 650, the substrate pads 420 may be on a portion of the second redistribution substrate 400 corresponding to the bonding ball 650. That is, the bonding balls 650 may be one-to-one coupled to the substrate pads 420 of the second redistribution substrate 400.

FIGS. 6A and 6B are a top view of a semiconductor package 1000c and a cross-sectional view of a semiconductor package 1000d according to embodiments, respectively. The description made with reference to FIGS. 1 to 5B is simply repeated or omitted.

Referring to FIG. 6A, the semiconductor package 1000c of the present embodiment may differ from the semiconductor package 1000 of FIG. 1 in that one first semiconductor device 200a includes two logic chips. Particularly, the semiconductor package 1000c of the present embodiment may include the first redistribution substrate 100, the first semiconductor device 200a, the through post 300, the second redistribution substrate 400, the second semiconductor device 500, the heat-dissipating block 600a, the sealant 700, and the passive device 800. The first redistribution substrate 100, the through post 300, the second redistribution substrate 400, the second semiconductor device 500, the heat-dissipating block 600, the sealant 700, and the passive device 800 are the same as described for the semiconductor package 1000 of FIG. 1.

In the semiconductor package 1000c of the present embodiment, the first semiconductor device 200a may include a first semiconductor chip 200-1 and a second semiconductor chip 200-2. The first semiconductor chip 200-1 and the second semiconductor chip 200-2 may be on the first redistribution substrate 100 so as to be adjacent to each other in a plan view. For example, as shown in FIG. 6A, the first semiconductor chip 200-1 and the second semiconductor chip 200-2 may be arranged in the y direction. Both the first semiconductor chip 200-1 and the second semiconductor chip 200-2 may be mounted on the first redistribution substrate 100 through the first connection terminal 250. As shown in FIG. 6A, the second redistribution substrate 400 may be on the first semiconductor chip 200-1 and the second semiconductor chip 200-2, and the heat-dissipating block 600 may be on the second redistribution substrate 400 so as to cover a most portion of the first semiconductor chip 200-1 and the second semiconductor chip 200-2.

In the semiconductor package 1000c of the present embodiment, each of the first semiconductor chip 200-1 and the second semiconductor chip 200-2 may include a logic chip. Accordingly, each of the first semiconductor chip 200-1 and the second semiconductor chip 200-2 may include a plurality of logic devices therein. For example, the first semiconductor chip 200-1 may be a modem chip supporting communication of the second semiconductor chip 200-2. However, the type of the first semiconductor chip 200-1 is not limited to the modem chip. For example, the first semiconductor chip 200-1 may include various types of integrated devices supporting an operation of the second semiconductor chip 200-2. The first semiconductor chip 200-1 may include a multi-channel input/output (I/O) interface configured to exchange a memory signal with the second semiconductor device 500. In addition, the first semiconductor chip 200-1 may include SRAM for temporary storage of data.

The second semiconductor chip 200-2 may include, for example, an AP chip. Alternatively, the second semiconductor chip 200-2 may include a control chip, a processor chip, a CPU chip, a GPU chip, an NPU chip, or the like. The second semiconductor chip 200-2 may include an SoC or constitute an SoC together with the first semiconductor chip 200-1.

Referring to FIG. 6B, the semiconductor package 1000d of the present embodiment may differ from the semiconductor package 1000 of FIG. 1 in that a first semiconductor device 200b includes two logic chips. Particularly, the semiconductor package 1000d of the present embodiment may include the first redistribution substrate 100, the first semiconductor device 200b, the through post 300, the second redistribution substrate 400, the second semiconductor device 500, the heat-dissipating block 600a, the sealant 700, and the passive device 800. The first redistribution substrate 100, the through post 300, the second redistribution substrate 400, the second semiconductor device 500, the heat-dissipating block 600, the sealant 700, and the passive device 800 are the same as described for the semiconductor package 1000 of FIG. 1.

In the semiconductor package 1000d of the present embodiment, the first semiconductor device 200b may include a first semiconductor chip 200a-1 and the second semiconductor chip 200-2. The first semiconductor chip 200a-1 and the second semiconductor chip 200-2 may be on the first redistribution substrate 100 in a stacked structure. For example, as shown in FIG. 6B, the second semiconductor chip 200-2 may be stacked on the first semiconductor chip 200a-1. The first semiconductor chip 200a-1 may be mounted on the first redistribution substrate 100 through the first connection terminal 250.

Each of the first semiconductor chip 200a-1 and the second semiconductor chip 200-2 may include a logic chip. Accordingly, each of the first semiconductor chip 200a-1 and the second semiconductor chip 200-2 may include a plurality of logic devices therein. The first semiconductor chip 200a-1 and the second semiconductor chip 200-2 may operate in substantially the same manner as the first semiconductor chip 200-1 and the second semiconductor chip 200-2 of the semiconductor package 1000c of FIG. 6A, respectively. However, because the second semiconductor chip 200-2 is stacked on the first semiconductor chip 200a-1, the internal structure of the first semiconductor chip 200a-1 may differ from that of the first semiconductor chip 200-1.

As shown in FIG. 6B, the first semiconductor chip 200a-1 may include a substrate, an active layer, and a through electrode 230. For example, in the first semiconductor chip 200a-1, with reference to a horizontal dotted line, an upper portion may be the substrate and a lower portion may be the active layer. The substrate and the active layer may be the same as described for the first semiconductor device 200 of the semiconductor package 1000 of FIG. 1. The through electrode 230 may extend through the substrate in the vertical direction, i.e., the z direction. The lower surface of the through electrode 230 may be connected to a wiring line of a multi-wiring layer of the active layer, and the upper surface of the through electrode 230 may be connected to the second semiconductor chip 200-2 by several connection methods. Therefore, the first semiconductor chip 200a-1 may be connected to the second semiconductor chip 200-2 via the through electrode 230. In addition, the first semiconductor chip 200a-1 may be connected to the second semiconductor device 500 via the first redistribution substrate 100, the through posts 300, and the second redistribution substrate 400. The several connection methods are described in more detail when stacking of the second semiconductor chip 200-2 is described below.

The through electrode 230 may be referred to as a through silicon via (TSV) because the through electrode 230 passes through the Si substrate of the first semiconductor chip 200a-1. As a reference, the through electrode 230 may be classified into a via-first structure formed before an integrated circuit layer of the active layer is formed, a via-middle structure formed before the multi-wiring layer of the active layer is formed after the integrated circuit layer is formed, and a via-last structure formed after the multi-wiring layer is formed. In FIG. 6B, the through electrode 230 may correspond to, for example, the via-middle structure. However, the through electrode 230 is not limited thereto, and in the semiconductor package 1000d of the present embodiment, the through electrode 230 may have the via-first or via-last structure.

In the first semiconductor chip 200a-1, the lower surface may be a front-side that is an active surface, and the upper surface may be a back-side that is an inactive surface. In other words, the lower surface of the active layer may correspond to the front-side of the first semiconductor chip 200a-1, and the upper surface of the substrate may correspond to the back-side of the first semiconductor chip 200a-1. A chip pad may be formed on the front-side that is an active surface, and the first semiconductor chip 200a-1 may be mounted on the first redistribution substrate 100 through the first connection terminal 250 on the chip pad.

The second semiconductor chip 200-2 may be mounted on the first semiconductor chip 200a-1 by several connection methods. For example, the second semiconductor chip 200-2 may be mounted on the first semiconductor chip 200a-1 by using a connection terminal. The connection terminal may be connected to the through electrode 230 of the first semiconductor chip 200a-1. In addition, the second semiconductor chip 200-2 may be mounted on the first semiconductor chip 200a-1 through pad-to-pad bonding, HB, bonding using an ACF, or the like. As a reference, because a pad is usually formed of Cu, pad-to-pad bonding is also referred to as Cu-to-Cu bonding.

Herein, pad-to-pad bonding may indicate that a chip pad of the second semiconductor chip 200-2 is directly connected to a pad on the through electrode 230 of the first semiconductor chip 200a-1, and HB may indicate a hybrid of pad-to-pad bonding and insulator-to-insulator bonding. In addition, the ACF through which electricity flows only in one direction may indicate a conductive film made in a film state by mixing fine conductive particles in an adhesive resin.

The second semiconductor chip 200-2 may also include a substrate at an upper portion thereof and an active layer at a lower portion thereof. However, unlike the first semiconductor chip 200a-1, the second semiconductor chip 200-2 may not include a through electrode. In the second semiconductor chip 200-2, the lower surface may be a front-side that is an active surface, and the upper surface may be a back-side that is an inactive surface. In other words, the lower surface of the active layer may correspond to the front-side of the second semiconductor chip 200-2, and the upper surface of the substrate may correspond to the back-side of the second semiconductor chip 200-2.

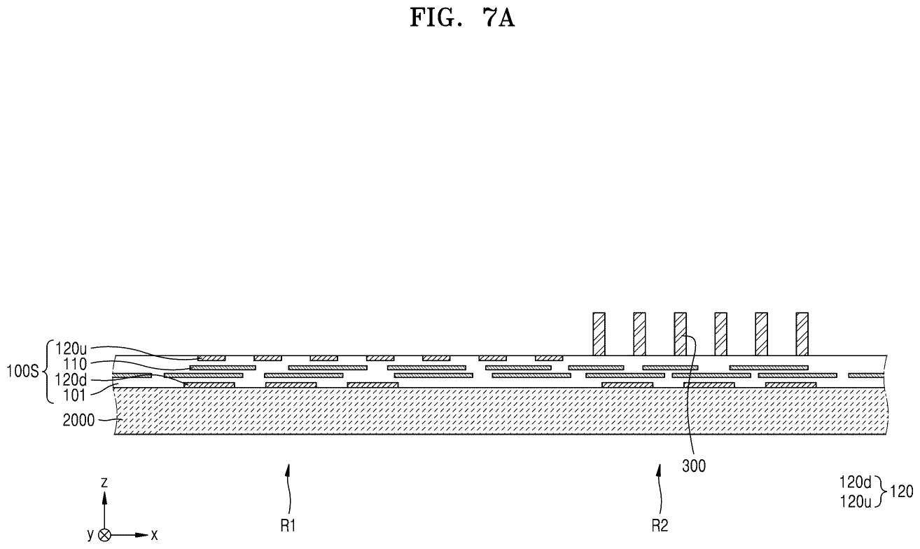

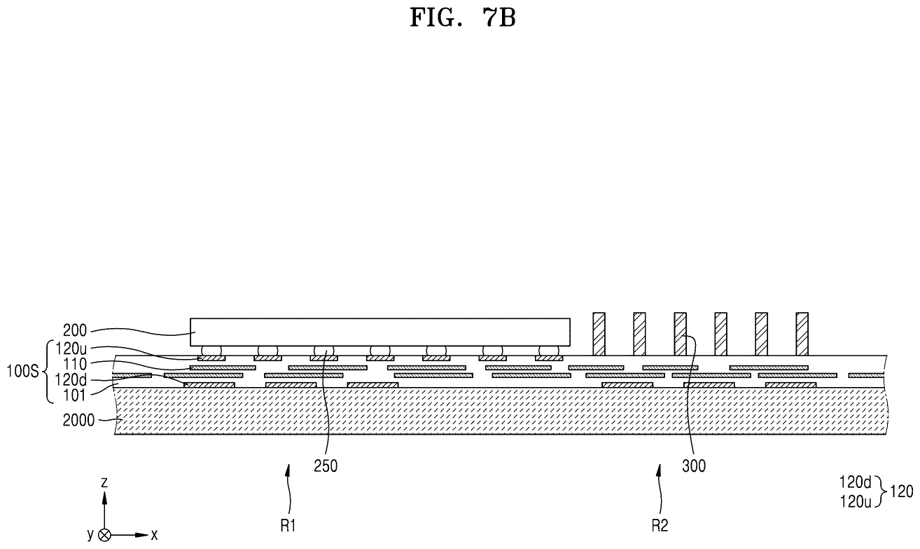

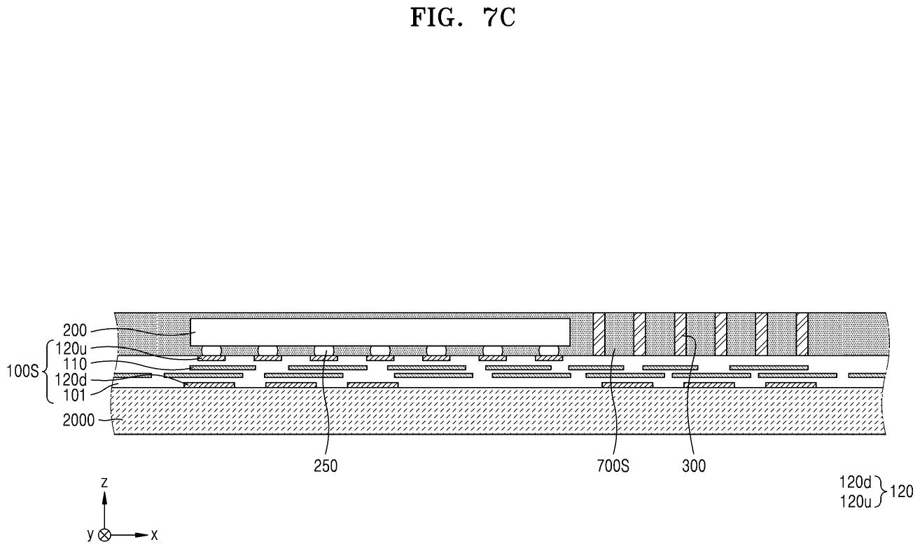

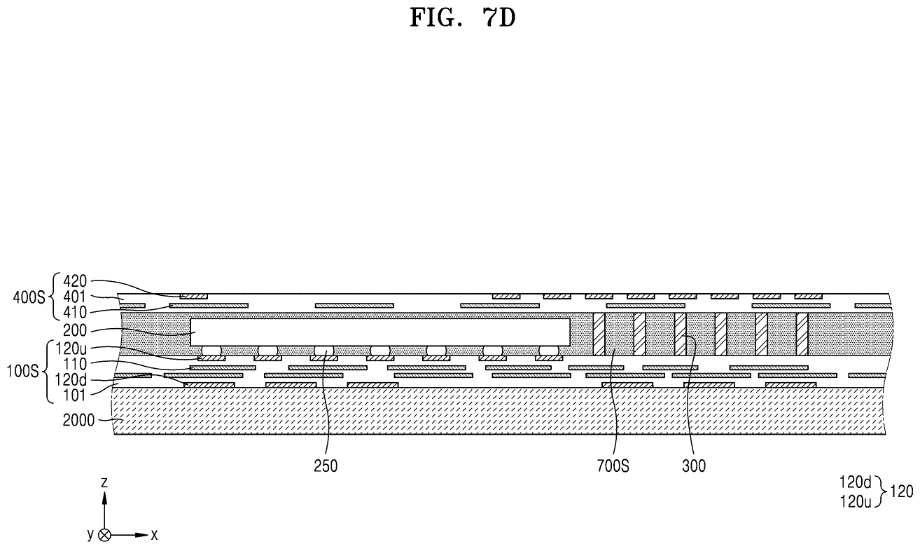

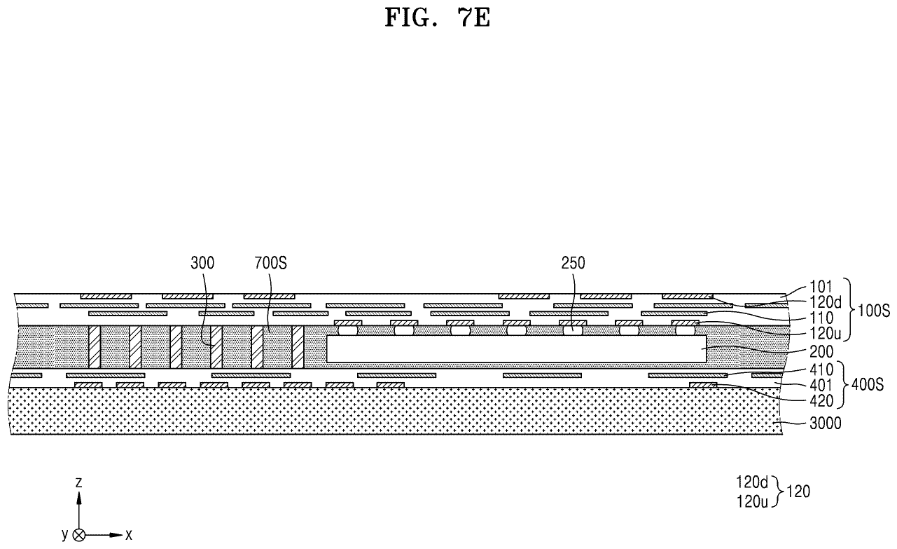

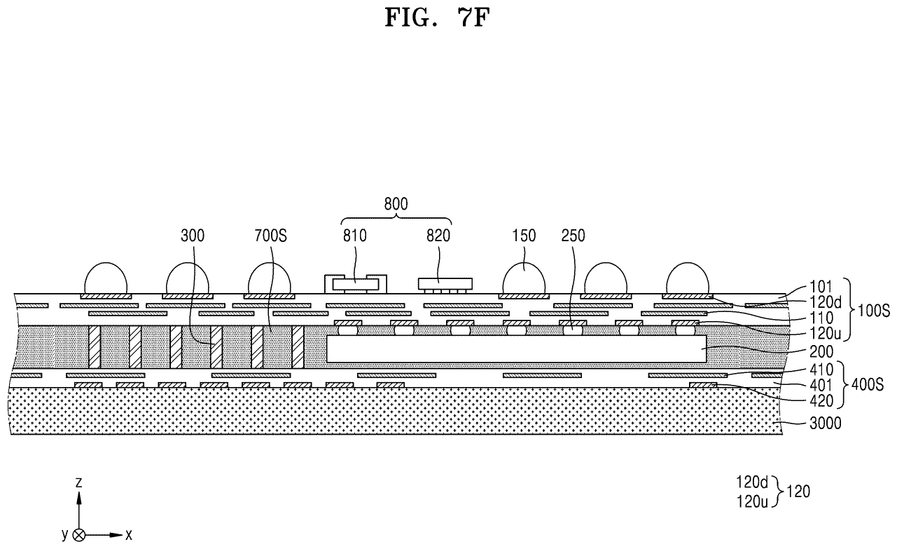

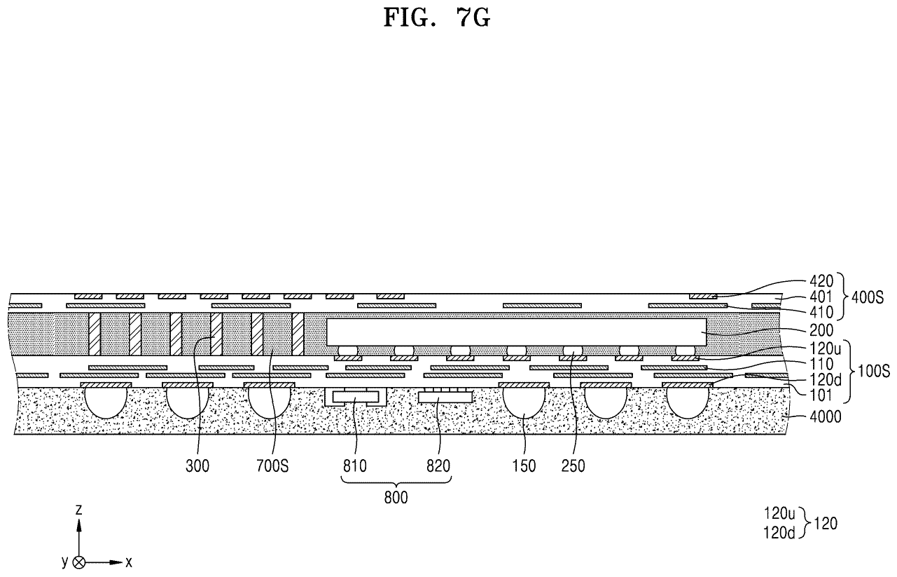

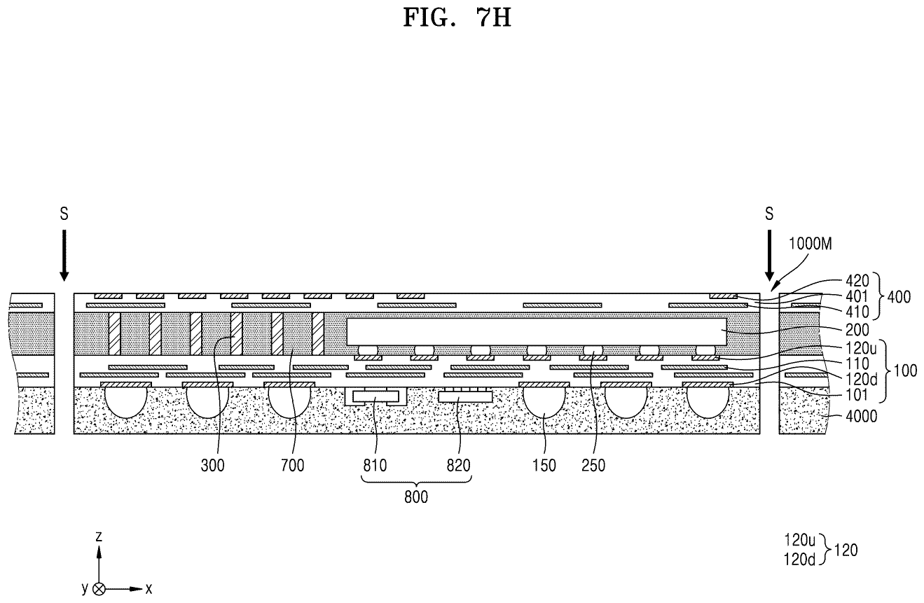

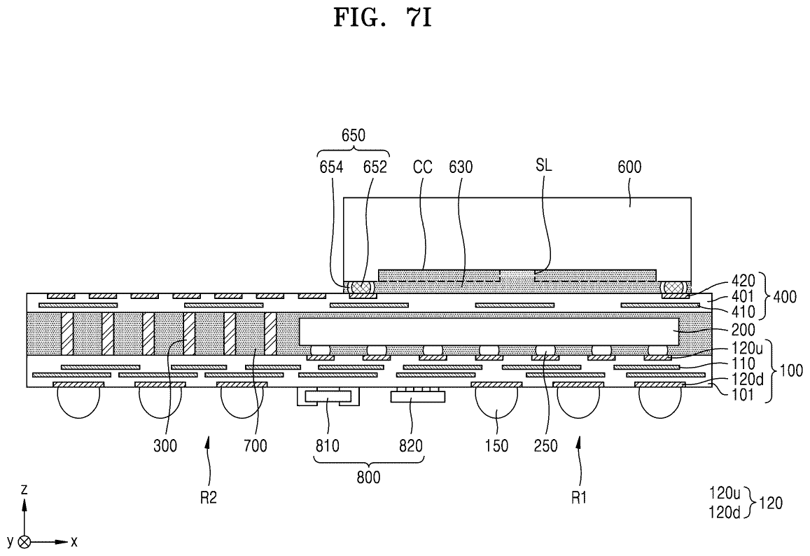

FIGS. 7A to 7I are cross-sectional views schematically illustrating a method of manufacturing a semiconductor package, according to an embodiment. FIG. 1 is also referred to for description, and the description made with reference to FIGS. 1 to 6B is simply repeated or omitted.

Referring to FIG. 7A, the method of manufacturing a semiconductor package, according to the present embodiment, may include, first, forming a lower redistribution substrate 100S. The lower redistribution substrate 100S may include the first body insulating layer 101, the first redistribution line 110, and the substrate pad 120. The lower redistribution substrate 100S may be formed on a first carrier substrate 2000. The first carrier substrate 2000 may be a large-size substrate, such as a wafer. In addition, the lower redistribution substrate 100S formed on the first carrier substrate 2000 may also be a large-size substrate including a plurality of first redistribution substrates 100. Although not shown in FIG. 7A, an adhesive layer may be between the lower redistribution substrate 100S and the first carrier substrate 2000. The adhesive layer may fix the lower redistribution substrate 100S onto the first carrier substrate 2000 in an adhesive manner.

As a reference, as described below, semiconductor packages may be manufactured by forming a plurality of components on a large-size redistribution substrate and then individualized through a sawing process or a singulation process, and such a manufactured semiconductor package is referred to as a wafer level package (WLP). Hereinafter, for convenience of description, in FIGS. 7A to 7I, only components corresponding to one first redistribution substrate 100 are shown.

After forming the lower redistribution substrate 100S, the through posts 300 are formed on the lower redistribution substrate 100S. The through posts 300 may be formed on the lower redistribution substrate 100S and at any one side, e.g., to the right, in the x direction by considering a portion where the first semiconductor device 200 is to be arranged later. For example, the lower redistribution substrate 100S may include a first region R1 and a second region R2. The through posts 300 may be formed on the second region R2 of the lower redistribution substrate 100. When a process of forming the through posts 300 is described in more detail, a seed metal layer and a photoresist (PR) layer are formed on the lower redistribution substrate 100S. Thereafter, a PR pattern is formed by performing a photo process on the PR layer. Herein, the photo process may include an exposure process, a development process, a cleaning process, and the like. The PR pattern may include a plurality of through holes, and a portion of the seed metal layer corresponding to the upper substrate pad 120u may be exposed on the bottom surface of a through hole. Thereafter, a plating process using the seed metal layer may be performed to form the through posts 300 inside the plurality of through holes, respectively. The through post 300 may include, for example, Cu. Thereafter, the PR pattern is removed through an ashing/strip process. In addition, after removing the PR pattern, the seed metal layer exposed between the through posts 300 is removed by an etching process. In the etching process, the seed metal layer beneath the through posts 300 may remain. In FIGS. 7A to 7I, the seed metal layer is included in the through posts 300 and is not separately shown.

Referring to FIG. 7B, after forming the through posts 300, the first semiconductor device 200 is mounted on the lower redistribution substrate 100S on which the through posts 300 are not disposed. That is, the first semiconductor device 200 is mounted on the lower redistribution substrate 100S and to the left of the through posts 300 in the x direction. The first semiconductor device 200 may be mounted on the first region R1 of the lower redistribution substrate 100S through the first connection terminal 250. The first semiconductor device 200 is the same as described for the semiconductor package 1000 of FIG. 1.

Referring to FIG. 7C, after mounting the first semiconductor device 200, a sealant 700S sealing the first semiconductor device 200 and the through posts 300 is formed. The sealant 700S may be formed by forming a sealing material layer that covers the first semiconductor device 200 and the through posts 300 and then removing an upper portion of the sealing material layer through a mold grinding (MG) process.

After the MG process, the upper surfaces of the through posts 300 may be exposed from the sealant 700S. In some embodiments, after the MG process, the upper surface of the first semiconductor device 200 may be exposed. The sealant 700S may have a size corresponding to the size of the lower redistribution substrate 100S. For example, the sealant 700S may be formed at a wafer level.

The sealant 700S may cover the side surfaces and the upper surface of the first semiconductor device 200 and the side surfaces of the through posts 300. In addition, the sealant 700S may fill between first connection terminals 250 on the lower surface of first semiconductor device 200. The material and the like of the sealant 700S are the same as described for the semiconductor package 1000 of FIG. 1.

Referring to FIG. 7D, thereafter, an upper redistribution substrate 400S is formed on the first semiconductor device 200, the through posts 300, and the sealant 700S. The upper redistribution substrate 400S may also include a body insulating layer, a redistribution line, and a substrate pad. The redistribution line of the upper redistribution substrate 400S may be connected to the through post 300.

The upper redistribution substrate 400S may include a plurality of second redistribution substrates 400. That is, the upper redistribution substrate 400S may be formed at a wafer level and have a size corresponding to the size of the lower redistribution substrate 100S.

In a process of forming the upper redistribution substrate 400S, the substrate pads 420 may be formed on the upper surface of the upper redistribution substrate 400S. The substrate pads 420 may include a group coupled to the second connection terminals 550 of the second semiconductor device 500 and a group coupled to the bonding balls 650 of the heat-dissipating block 600. When the semiconductor package 1000a of FIG. 4 is manufactured, the substrate pads 420 may include only the group coupled to the second connection terminals 550 of the second semiconductor device 500.

Referring to 7E, after forming the upper redistribution substrate 400S, the lower redistribution substrate 100S and structures thereon are separated from the first carrier substrate 2000, upside down, and attached to a second carrier substrate 3000. In other words, as shown in FIG. 7E, the upper redistribution substrate 400S may be attached onto the second carrier substrate 3000, the first semiconductor device 200, the through posts 300, and the sealant 700S may be disposed on the upper redistribution substrate 400S, and the lower redistribution substrate 100S may be disposed on the first semiconductor device 200, the through posts 300, and the sealant 700S. Although not shown in FIG. 7E, an adhesive layer may be between the upper redistribution substrate 400S and the second carrier substrate 3000.

Referring to FIG. 7F, thereafter, the external connection terminal 150 is attached onto the upper surface of the lower redistribution substrate 100S. In FIG. 7F, the upper surface of the lower redistribution substrate 100S may correspond to the lower surface of the first redistribution substrate 100 in the semiconductor package 1000 of FIG. 1. The external connection terminal 150 is the same as described for the semiconductor package 1000 of FIG. 1. In addition, in a process of attaching the external connection terminal 150, the passive device 800 may be attached onto the upper surface of the lower redistribution substrate 100S through a surface mount technology (SMT) process or the like.

Referring to FIG. 7G, after attaching the external connection terminal 150 onto the lower redistribution substrate 100S, the upper redistribution substrate 400S and structures thereon are separated from the second carrier substrate 3000, upside down again, and attached to a ring mount 4000. For example, as shown in FIG. 7G, the external connection terminal 150 and the passive device 800 on the lower redistribution substrate 100S are attached to a mounting tape of the ring mount 4000.

Referring to FG. 7H, thereafter, a sawing process S on the lower redistribution substrate 100S and the structures thereon may be performed. Through the sawing process S, the lower redistribution substrate 100S and the structures thereon may be individualized. Through the individualization, an intermediate semiconductor package 1000M including the first redistribution substrate 100, the first semiconductor device 200, the through posts 300, the second redistribution substrate 400, and the sealant 700 may be manufactured.

Referring to FIG. 7I, after manufacturing the intermediate semiconductor package 1000M, the heat-dissipating block 600 is stacked on the second redistribution substrate 400. The heat-dissipating block 600 may be stacked on the second redistribution substrate 400 through the adhesive layer 630 and the bonding balls 650. The heat-dissipating block 600 may be stacked on the second redistribution substrate 400 and to the right in the x direction so as to correspond to the first semiconductor device 200. The heat-dissipating block 600 may stacked on a first region R1 of the second redistribution substrate 400 and the second redistribution substrate 400 may include a second region R2 next to the first region R1 of the second redistribution substrate 400. The structure of the heat-dissipating block 600 is the same as described for the semiconductor package 1000 of FIG. 1. When the semiconductor package 1000a or 1000b of FIG. 4 or 5A is manufactured, the heat-dissipating block 600 or 600a may be stacked on the second redistribution substrate 400 instead of the heat-dissipating block 600.

Thereafter, the second semiconductor device 500 may be mounted on the second redistribution substrate 400 through the second connection terminal 550 to complete the semiconductor package 1000 of FIG. 1. The second semiconductor device 500 may be mounted on the second redistribution substrate 400 and to the left in the x direction so as to correspond to the through posts 300. The second semiconductor device 500 may be mounted on the second region R2 of the second redistribution substrate 400.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While inventive concepts have been particularly shown and described with reference to embodiments thereof, it will be understood that various changes in form and details may be made therein without departing from the spirit and scope of the following claims.

What is claimed is:

1. A semiconductor package comprising:
a first redistribution substrate including a first region and a second region next to each other in a first direction;
a first semiconductor device on the first region of the first redistribution substrate;
through posts on the second region of the first redistribution substrate, such that the first semiconductor device is adjacent to the through posts in the first direction;
a second redistribution substrate on the first semiconductor device and the through posts, the second redistribution substrate including a first region and a second region next to each other in the first direction;
a second semiconductor device on the second region of the second redistribution substrate;
a heat-dissipating block on the first region of the second redistribution substrate and adjacent to the second semiconductor device, wherein
a center portion of a lower surface of the heat-dissipating block comprises a recessed portion; and
an adhesive layer filling the recessed portion of the heat-dissipating block and coupling the heat-dissipating block to the second redistribution substrate.

2. The semiconductor package of claim 1, wherein
an edge portion of the lower surface of the heat-dissipating block includes a protruding portion, and
the protruding portion of the heat-dissipating block surrounds the recessed portion of the heat-dissipating block.

3. The semiconductor package of claim 2, wherein
the protruding portion of the heat-dissipating block has a slit forming an opening in fluid communication with the recessed portion of the heat-dissipating block, and
the slit is filled with the adhesive layer.

4. The semiconductor package of claim 3, wherein
the lower surface of the heat-dissipating block has a rectangular shape,
the protruding portion extends along four sides of the rectangular shape, and
at least one slit is in each side among the four sides of the rectangular shape.

5. The semiconductor package of claim 2, further comprising:
bonding balls are on a lower surface of the protruding portion.

6. The semiconductor package of claim 5, wherein
each of the bonding balls comprises a copper (Cu) ball at a center thereof and a solder ball on an outside the Cu ball.

7. The semiconductor package of claim 1, wherein the adhesive layer includes silicon (Si).

8. The semiconductor package of claim 1, wherein
the first semiconductor device comprises a logic device, and
the second semiconductor device comprises a memory device.

9. The semiconductor package of claim 8, wherein the second semiconductor device has a single-chip structure or a package structure having a plurality of chips.

10. The semiconductor package of claim 8, wherein the first semiconductor device comprises a plurality of chips.

11. A semiconductor package comprising:
a first redistribution substrate including a first region and a second region by each other in a first direction;
a first semiconductor device on the first region of the first redistribution substrate;
through posts on the second region of the first redistribution substrate and adjacent to the first semiconductor device;
a second redistribution substrate on the first semiconductor device and the through posts, the second redistribution substrate including a first region and a second region by each other in the first direction;
a second semiconductor device on the second region of the second redistribution substrate, the second semiconductor device over the through posts;
a heat-dissipating block on the first region of the second redistribution substrate;
an adhesive layer on the first region of the second redistribution substrate and over the first semiconductor device, the adhesive layer being adjacent to the second semiconductor device, the adhesive layer between the second redistribution substrate and the heat-dissipating block; and
bonding balls along an edge portion of a lower surface of the heat-dissipating block.

12. The semiconductor package of claim 11, wherein
the adhesive layer is at a center portion of the lower surface of the heat-dissipating block, and
the adhesive layer is between the bonding balls.

13. The semiconductor package of claim 11, wherein each of the bonding balls comprises a copper (Cu) ball at a center thereof and a solder ball outside the Cu ball.

14. The semiconductor package of claim 11, wherein
a center portion of the lower surface of the heat-dissipating block includes a recessed portion, and
the recessed portion of the heat-dissipating block is surrounded by a protruding portion of the heat-dissipating block.

15. The semiconductor package of claim 14, wherein the bonding balls are on a lower surface of the protruding portion.

16. The semiconductor package of claim 14, wherein
the protruding portion of the heat-dissipating block has a slit forming an opening in fluid communication with the recessed portion of the of the heat-dissipating block,
the slit is filled with the adhesive layer.

17. A semiconductor package comprising:
a first redistribution substrate including a first region and a second region next to each other in a first direction;
a first semiconductor device on the first region of the first redistribution substrate;
through posts on the second region of the first redistribution substrate and adjacent to the first semiconductor device;
a second redistribution substrate on the first semiconductor device and the through posts, the second redistribution substrate including a first region and a second region next to each other in the first direction;
a second semiconductor device on the second region of the second redistribution substrate;
an adhesive layer and bonding balls on first region of the second redistribution substrate and adjacent to the second semiconductor device;
a heat-dissipating block connected to the first region of the second redistribution substrate through the bonding balls and the adhesive layer; and
a sealant between the first redistribution substrate and the second redistribution substrate, the sealant sealing the first semiconductor device and the through posts,
wherein a center portion of a lower surface of the heat-dissipating block comprises a recessed portion,
an edge portion of the lower surface of the heat-dissipating block includes a protruding portion,
the protruding portion of the heat-dissipating block surrounds the recessed portion of the heat-dissipating block,
the adhesive layer fills the recessed portion of the heat-dissipating block, and
the protruding portion has a slit forming an opening in fluid communication with the recessed portion of the heat-dissipating block.

18. The semiconductor package of claim 17, wherein
the lower surface of the heat-dissipating block has a rectangular shape,
the protruding portion extends along four sides of the rectangular shape, and
a slit is in each side of the protruding portion.

19. The semiconductor package of claim 17, wherein
the bonding balls are on a lower surface of the protruding portion, and
the adhesive layer fills between the bonding balls and fills in the slit.

20. The semiconductor package of claim 17, wherein
the first semiconductor device comprises a plurality of logic chips, and
the second semiconductor device has a package structure having a plurality of memory chips.
